(19) United States
(12) Patent Application Publication
(10) Pub. No.: US 2026/0136966 A1
(43) Pub. Date: May 14, 2026

(54) MICROELECTRONIC ASSEMBLIES INCLUDING A PHOTOPOLYMER LINER IN THROUGH-GLASS VIAS

(71) Applicant: Intel Corporation, Santa Clara, CA (US)

(72) Inventors: Whitney Bryks, Tempe, AZ (US); Hiroki Tanaka, Gilbert, AZ (US); Aaditya Candadai, Chandler, AZ (US); Joseph Peoples, Gilbert, AZ (US)

(73) Assignee: Intel Corporation, Santa Clara, CA (US)

(21) Appl. No.: 18/947,614

(22) Filed: Nov. 14, 2024

(51) Int. Cl. H01L 23/498; H01L 23/00; H01L 23/15; H01L 25/065

(52) U.S. Cl. CPC H10W 70/65; H10W 70/685; H10W 70/692; H10W 90/00; H10W 72/823; H10W 72/90; H10W 74/15; H10W 90/28; H10W 90/722; H10W 90/724

(57) ABSTRACT

Disclosed herein are microelectronic assemblies and related devices and methods for alleviating stresses in through-glass vias by providing a photopolymer liner. In some embodiments, a microelectronic assembly may include a glass core with a through-glass via (TGV), where the TGV includes a conductive material; and a liner material between the glass core and the conductive material of the TGV, where the liner material includes a photopolymer. In some embodiments, a microelectronic assembly may include a glass layer; a cavity in a surface of the glass layer, the cavity having sidewalls; and a liner material on the sidewalls of the cavity, where the liner includes a photopolymer.

### BACKGROUND

For the past several decades, scaling of features in integrated circuits (ICs) has been a driving force behind an ever-growing semiconductor industry and emerging applications in fields such as big data, artificial intelligence, mobile communications, and autonomous driving. Scaling to smaller and smaller features enables increased densities of functional units on the limited real estate of semiconductor chips. For example, shrinking transistor size allows incorporation of an increased number of memory or logic devices on a chip, lending to the fabrication of products with increased capacity. The drive for the ever-increasing capacity, however, is not without issue. The necessity to optimize fabrication and performance of each component (e.g., of each transistor) is becoming increasingly significant.

Parallel to optimizations at the transistor level, advanced IC packaging landscape is rapidly evolving to accommodate performance expectations and requirements of shrinking transistor size. Multiple IC dies are now commonly coupled together in a multi-die IC package to integrate features or functionality and to facilitate connections to other components, such as package substrates. For example, IC packages may include an embedded multi-die interconnect bridge (EMIB) for coupling two or more IC dies.

Integration of multiple dies in a single IC package has tremendous benefits but adds additional complexities due to placing materials with different material properties in close proximity to one another. When an IC package undergoes multiple processing steps involving various temperatures and pressure loads, individual materials within the package may behave differently from one another, resulting in out of plane deformation of various layers, known as “package warpage.” One way to address package warpage is to use stiffer cores to which different IC dies are attached. Recently, glass cores have been explored as alternatives to organic resin-based cores (e.g., cores based on using Ajinomoto Build-up Film(ABF)). Glass is considered more rigid than organic resin-based materials and has several advantages such as excellent thermal properties, low coefficient of thermal expansion (CTE), high electrical insulation, chemical resistance, optical transparency, and compatibility with advances semiconductor properties. However, a major challenge for widespread adoption of glass cores is the fact that glass is highly susceptible to damage due to mechanical and/or thermal stresses, e.g., damage due to stresses caused by through-glass vias (TGVs) filled with metals.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic side, cross-sectional view of an example microelectronic assembly according to some embodiments of the present disclosure.

FIG. 2 is a schematic side, cross-sectional view of another example microelectronic assembly according to some embodiments of the present disclosure.

FIG. 3 illustrates surfaces of a glass core from which TGV stress may initiate, according to some embodiments of the present disclosure.

FIGS. 4A-4D are simplified schematic side, cross-sectional views of example portions of a microelectronic assembly according to some embodiments of the present disclosure.

FIGS. 5A and 5B are simplified schematic side, cross-sectional views of another example portions of a microelectronic assembly according to some embodiments of the present disclosure.

FIGS. 6A-6F are simplified side, cross-sectional views illustrating various manufacturing steps of an example microelectronic assembly according to some embodiments of the present disclosure.

FIG. 7 is a cross-sectional view of a device package that may include one or more microelectronic assemblies in accordance with any of the embodiments disclosed herein.

FIG. 8 is a cross-sectional side view of a device assembly that may include one or more microelectronic assemblies in accordance with any of the embodiments disclosed herein.

FIG. 9 is a block diagram of an example computing device that may include one or more microelectronic assemblies in accordance with any of the embodiments disclosed herein.

### DETAILED DESCRIPTION

The structures and assemblies disclosed herein may include a glass core, also referred to herein as a “glass layer,” with TGVs extending through the glass core for front-to-back connections between two different substrates. A substrate may include a dielectric material with conductive pathways therein that are typically formed on a surface of the glass core. The conductive pathways through the dielectric material may provide routing for design flexibility, and the uniform diameters of the TGVs may provide dimensional stability and improved connectivity. A glass core as compared to a conventional epoxy core offers several advantages including higher TGV density, lower signal losses, and lower total thickness variation (TTV), among others. Another advantage is a glass core enables higher aspect ratio TGVs. Higher aspect ratio TGVs are required to achieve the finer pitches that are desired. In some implementations, TGVs may extend between the top and the bottom surfaces of a glass core, e.g., to provide electrical connectivity between electronic components such as dies and/or package substrates, coupled to the top and bottom surfaces of the glass core. In other implementations, TGVs may be blind vias that extend from the top/bottom surface of the glass core towards, but not reaching, the opposite surface, e.g., to provide electrical connectivity from a surface of the glass core to a conductive trace or an IC component embedded in the glass core. TGVs may also support efficient thermal management by providing paths for heat dissipation from the active components to the package's external environment.

As mentioned above, glass has properties that make it promising for integration in advanced IC packaging. Provision of TGVs in glass cores enables more compact and efficient designs for microelectronic assemblies. However, the integration of TGVs in glass cores is not trivial. Conventionally, fabrication of TGVs includes forming openings for future TGVs, lining the openings with a seed material, and then depositing a conductive bulk fill material into the lined openings. The seed material typically includes a low-resistivity metal such as copper that can be deposited in a thin layer on substantially non-conductive surfaces (e.g., sidewalls) of openings in a glass core. The seed material is intended to provide conductive surfaces for uniform and controlled deposition of the conductive bulk fill material in a subsequent deposition step, e.g., when the conductive bulk fill material is deposited in the lined openings using a process such as electroplating. One challenge associated with integration of TGVs in glass cores arises from the differences in CTEs (a phenomenon sometimes referred to as a “CTE mismatch”) between materials that may be used for glass cores and the metals of the seed material and the conductive bulk fill material deposited in the TGVs. CTE is a measure of how a material expands or contracts with changes in temperature. CTE is typically defined as the fractional increase in length per unit rise in temperature, measured in, e.g., parts per million (ppm) per degrees Kelvin (K) or ppm/K. Glass materials that may be used for glass cores and metals have significantly different CTEs. Metals have relatively high CTEs, meaning that they may expand and contract significantly with changes in temperature. Glass materials, on the other hand, have much lower CTEs and are less responsive to temperature changes. For example, a CTE of a glass material may be on the order of about 3.5 ppm/K, while a CTE of a metal such as copper may be on the order of about 15-17 ppm/K. When a metal is in close contact with glass (e.g., a seed material or a conductive bulk fill material within a TGV in a glass structure), and the assembly is exposed to temperature variations such as heating or cooling, the metal will heat up or cool down much faster, and to a greater extent, than glass. This leads to generation of significant stresses at the interface between the two materials. For example, a metal that is expanding may cause compressive stress, while a metal that is contracting may cause tensile stress. Sufficiently high stress can exceed the strength of glass, leading to formation of cracks which may then propagate and compromise the structural integrity of glass. Even if cracks don't form immediately, the repeated thermal cycling can gradually weaken glass, potentially leading to the development of surface flaws or micro-cracks. Prolonged exposure to CTE mismatch-induced stresses can cause gradual degradation of glass, making it more prone to failure over time.

Embodiments of the present disclosure relate to techniques, as well as to related devices and methods, for alleviating (e.g., mitigating or reducing) CTE mismatch-induced stresses caused by the proximity of conductive materials of TGVs to glass materials of glass cores. As used herein, such stresses are referred to as “TGV stresses.” Embodiments of the present disclosure are based on recognition that including a photopolymer liner on sidewalls of TGVs that act as a buffer layer between the glass core and conductive material(s) in the TGVs may help reduce TGV stress because the photopolymer liner separates the glass from the conductive bulk fill material deposited in the TGVs. As used herein, a photopolymer includes a type of polymer that changes its properties (e.g., solidifies) when exposed to certain wavelengths of light, typically ultraviolet (UV) light.

Accordingly, disclosed herein are microelectronic assemblies and related devices and methods. In some embodiments, a microelectronic assembly may include a glass core with a through-glass via (TGV), where the TGV includes a conductive material; and a liner material between the glass core and the conductive material of the TGV, where the liner material includes a photopolymer. In some embodiments, a microelectronic assembly may include a glass layer; a cavity in a surface of the glass layer, the cavity having sidewalls; and a liner material on the sidewalls of the cavity, where the liner includes a photopolymer.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are stated in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may include substantially monocrystalline semiconductors, such as silicon or germanium, as a base material on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a semiconductor-on-insulator (SOI, e.g., a silicon-on-insulator) structure. In some other embodiments, the base material of one or more of the IC dies may include alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may include compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may include an intrinsic IV or III-V semiconductor material or alloy, not intentionally doped with any electrically active impurity; in alternate embodiments, nominal impurity dopant levels may be present. In still other embodiments, dies may include a non-crystalline material, such as polymers; for example, the base material may include silica-filled epoxy. In other embodiments, the base material may include high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N-or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of input/output (I/O) functions, arithmetic operations, pipelining of data, etc.).

In another example, the terms “package” and “IC package” are synonymous, as are the terms “die” and “IC die.” Note that the terms “chip,” “chiplet,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may include a semiconductor material, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may include a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., metal oxide semiconductor (MOS) FETs (MOSFETs). In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are included in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a PIC, “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO2), borosilicate (e.g., 70-80 wt % SiO2, 7-13 wt % of B2O3, 4-8 wt % Na2O or K2O, and 2-8 wt % of Al2O 3) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material includes interlayer low-k dielectric that is provided within the IC die. Within package substrates, and printed circuit boards (PCBs) such insulating material includes organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI). Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects. In some embodiments, the pitch of the DTD interconnects may be different from the pitch of the DTPS interconnects, although, in other embodiments, these pitches may be substantially the same.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may include the same or different insulating materials. In some embodiments, the levels of underfill may include thermoset epoxies with silicon oxide particles; in some embodiments, the levels of underfill may include any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable dielectrics, dry film photoimageable dielectrics, acrylics, solvents) may be provided in an IC package described herein and may not be labeled or shown to avoid cluttering the drawings. Solder resist may be a liquid or dry film material including photoimageable dieletrics. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

Coordinates, when included in the accompanying drawings, identify a thickness or a height by z-dimension, a width by y-dimension, and a length by x-dimension. A diameter or cross section may be identified by xy-dimension.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, X-ray scanning electron microscopy (XSEM) images, or non-contact profilometer. In such images, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging. Further, a material composition may be determined using X-ray Photoelectron Spectroscopy (XPS), Fourier Transform Infrared Spectroscopy (FTIR), and/or Raman Spectroscopy.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

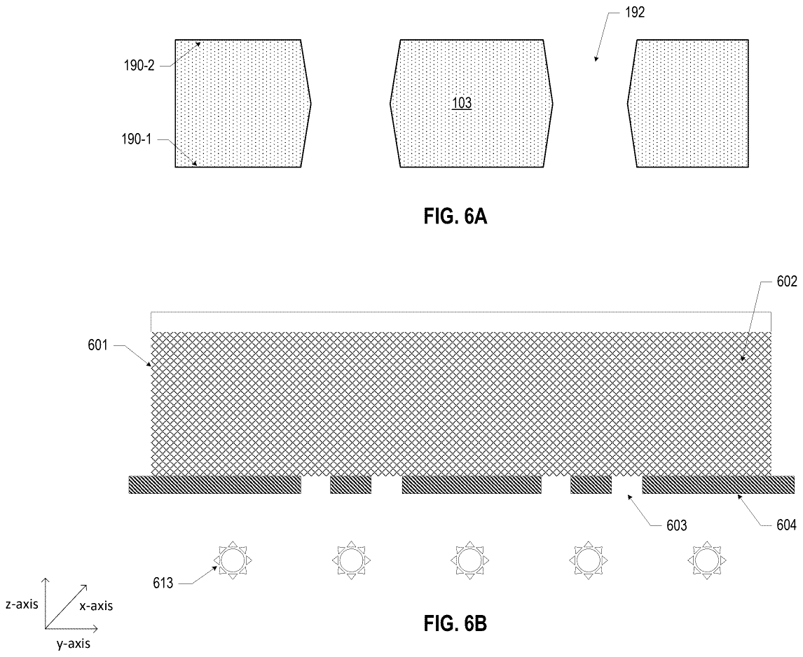

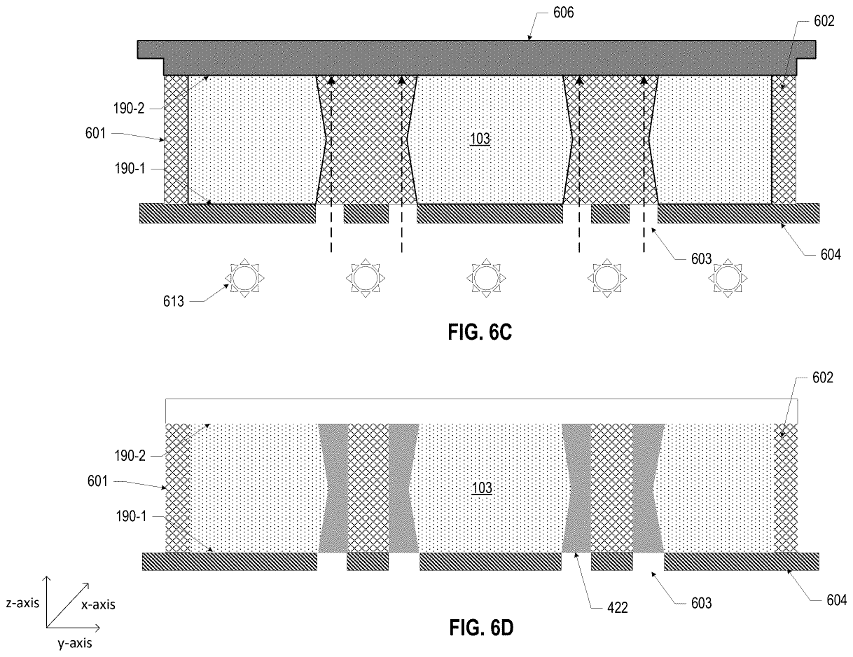

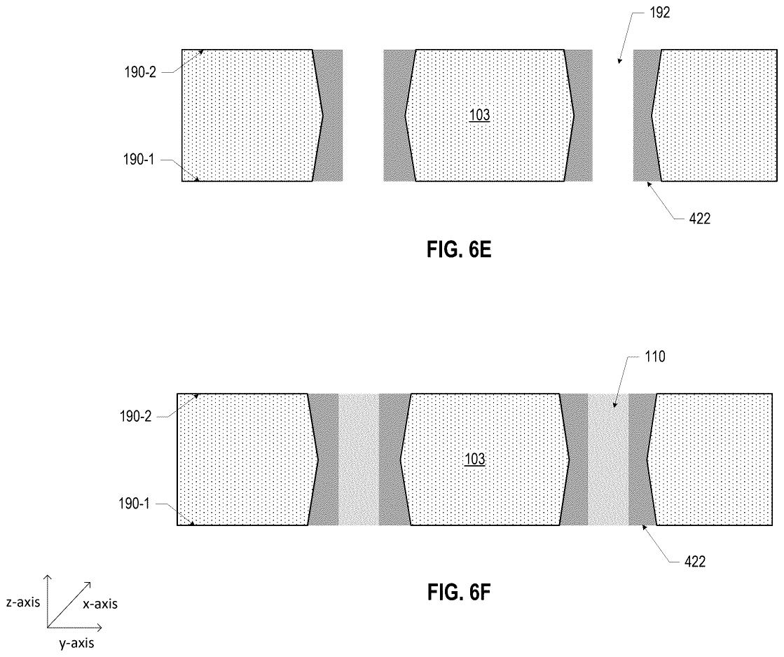

For convenience, if a collection of drawings designated with different letters are present (e.g., FIGS. 6A-6F), such a collection may be referred to herein without the letters (e.g., as “FIG. 6”). Similarly, if a collection of reference numerals designated with different numbers and/or letters are present (e.g., 148-1, 148-2), such a collection may be referred to herein without the numbers (e.g., as “148”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

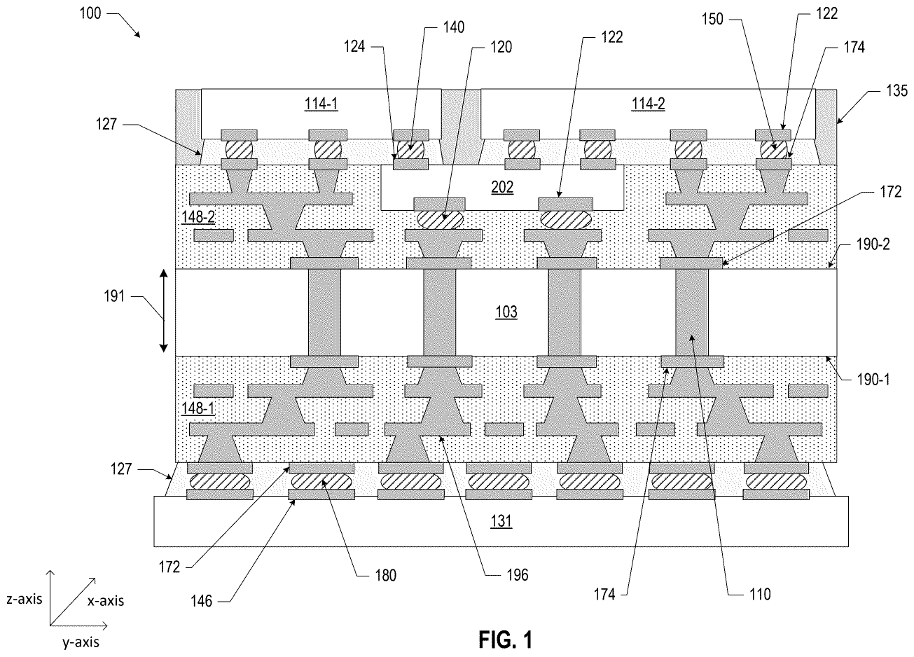

FIG. 1 is a schematic cross-sectional view of an example microelectronic assembly 100 in which a glass core having TGVs with a photopolymer liner as described herein may be implemented, according to some embodiments of the present disclosure. Microelectronic assembly 100 may include a glass core 103 having a first surface 190-1, a second surface 190-2 opposite the first surface 190-1, and a TGV 110 extending between the first surface 190-1 and the second surface 190-2.

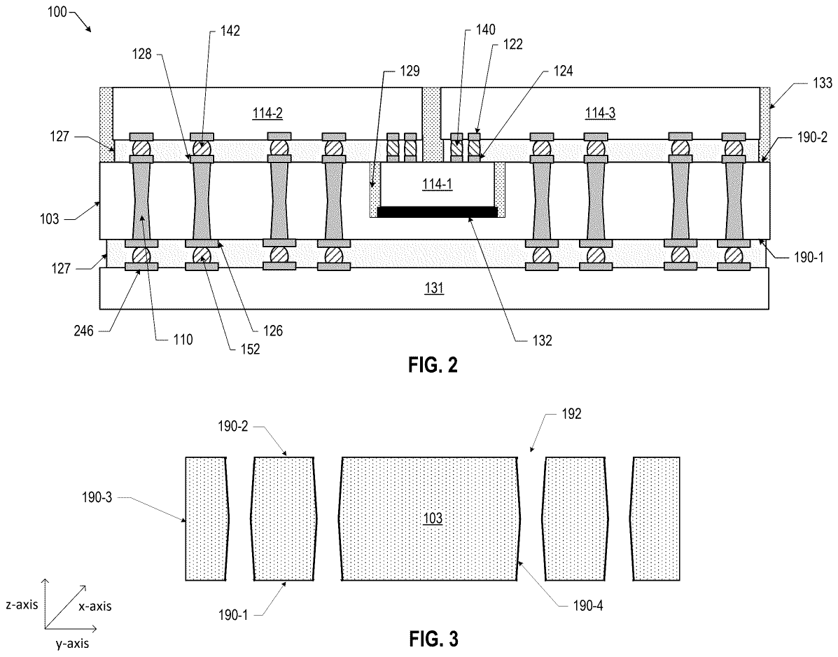

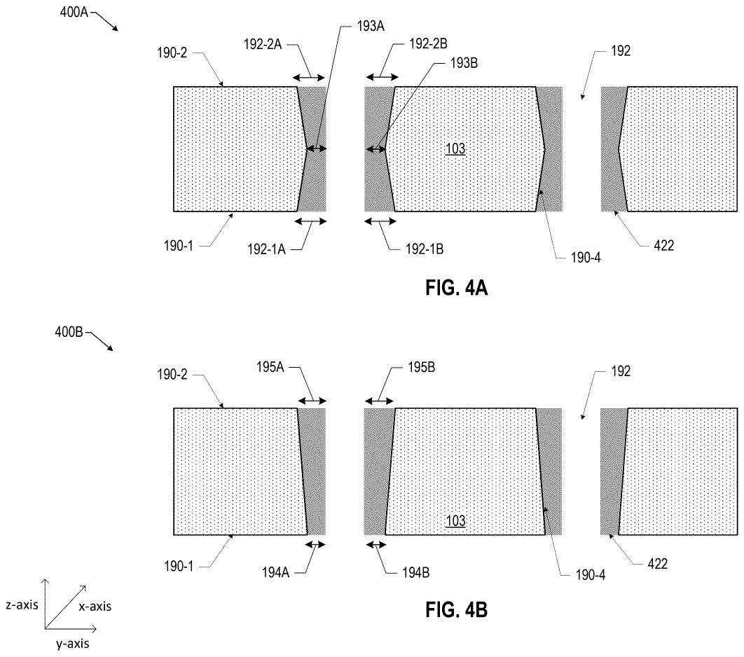

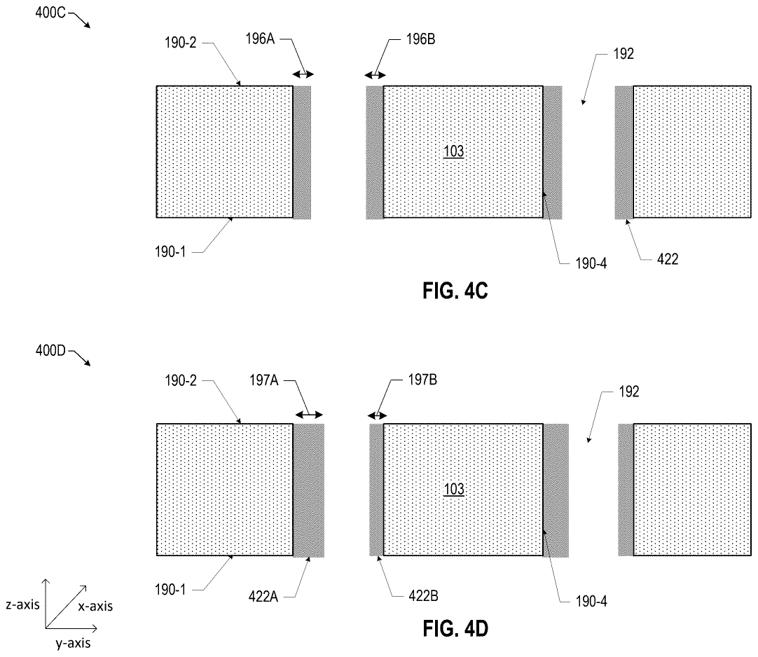

Any of the TGVs 110 may be a conductive via with a photopolymer liner as described herein. TGVs 110 may have any suitable size and shape. A thickness (e.g., z-dimension) of the individual TGVs 110 may be between 50 microns and 2 millimeters (i.e., between 200 microns and 1 millimeter). A diameter (e.g., xy-dimension) of the individual TGVs 110 may be between 5 microns and 200 microns (e.g., between 50 microns and 100 microns). In some embodiments, TGVs 110 have an aspect ratio between 2:1 and 30:1. An aspect ratio of a TGV 110 is the ratio of an overall thickness 191 (e.g., z-dimension or z-height) of the TGV to a diameter (e.g., xy-dimension) of the TGV, for example, a TGV having a thickness of 200 microns and a diameter of 20 microns has an aspect ratio equal to 10:1. TGVs 110 are shown in FIG. 1 (and in FIG. 4C) as having straight sides; however, in various embodiments, the TGVs 110 may have sides that taper toward a middle (e.g., have an hourglass shape, as shown in FIGS. 2 and 4A), may have sides that taper toward a first surface 190-1 or a second surface 190-2 (e.g., have a V-shape, as shown in FIG. 4B), and/or may have other irregularities depending on the processing conditions for generating TGVs 110. TGVs 110 may be formed using any suitable process, including, for example, via openings may be formed by laser activation and wet etch, laser ablation, or laser drilling, and a conductive material may be deposited in the via openings. TGVs 110 may be formed of any suitable conductive material, such as copper, silver, nickel, gold, aluminum, or other metals or alloys. In some embodiments, a pitch of the TGVs 110 may be between 25 microns and 200 microns (e.g., between 75 microns and 150 microns).

A glass core 103 may have an overall thickness 191 (e.g., z-dimension or z-height) between 50 microns and 2 millimeters (i.e., between 200 microns and 1 millimeter). A material of the glass core 103 may include glass, such as bulk transparent glass, and also may be referred to herein as “a glass layer.” As used herein, the term “core” refers to a structure (e.g., a portion of a glass layer) of any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, the glass core 103 may be bulk glass or a solid volume/layer of glass, as opposed to, e.g., materials that may include particles of glass, such as glass fiber reinforced polymers. Such glass materials are typically non-crystalline, often transparent, amorphous solids. In some embodiments, the glass core 103 may be an amorphous solid glass layer. In some embodiments, the glass core 103 may include silicon and oxygen, as well as any one or more of aluminum, boron, magnesium, calcium, barium, tin, sodium, potassium, strontium, phosphorus, zirconium, lithium, titanium, and zinc. In some embodiments, the glass core 103 may include a material, e.g., any of the materials described above, with a weight percentage of silicon being at least about 0.5%, e.g., between about 0.5% and 50%, between about 1% and 48%, or at least about 23%. For example, if the glass core 103 is fused silica, the weight percentage of silicon may be about 47%. In some embodiments, the glass core 103 may include at least 23% silicon and/or at least 26% oxygen by weight, and, in some further embodiments, the glass core 103 may further include at least 5% aluminum by weight. In some embodiments, the glass core 103 may include any of the materials described above and may further include one or more additives such as Al₂O₃, B₂O₃, MgO, CaO, SrO, BaO, SnO₂, Na₂O, K₂O, SrO, P₂O₃, ZrO₂, Li₂O, Ti, and Zn. In some embodiments, the glass core 103 may be a layer of glass that does not include an organic adhesive or an organic material. The glass core 103 may be distinguished from, for example, the “prepreg” or “RF4” core of a PCB substrate which typically includes glass fibers embedded in a resinous organic material such as an epoxy. In some embodiments, a cross-section of the glass core 103 in an xz plane, an yz plane, and/or an xy plane of an example coordinate system, shown in FIG. 1, may be substantially rectangular.

The microelectronic assembly 100 may further include a first substrate 148-1 at the first surface 190-1 of the glass core 103 and a second substrate 148-2 at the second surface 190-2 of the glass core 103. The first and second substrates 148-1, 148-2 may include conductive pathways 196 (e.g., including conductive traces and/or conductive vias, as shown) through a dielectric material. The substrates 148 may include a set of first conductive contacts 172 at the bottom surface of the substrate 148 and a set of second conductive contacts 174 at the top surface of the substrate 148, where the conductive pathways 196 electrically couple individual ones of the first and second conductive contacts 172, 174. In some embodiments, conductive contacts 174, 172 at respective first and second surfaces 190-1, 190-2 of the core 103 may be omitted.

The first and second substrates 148-1, 148-2 may be manufactured using any suitable technique, such as a semi-additive process, a subtractive etching technique, or other conventional substrate package techniques. In some embodiments, a dielectric material of the substrate 148 may include bismaleimide triazine (BT) resin, polyimide materials, epoxy materials (e.g., glass reinforced epoxy matrix materials, epoxy build-up films, or the like), mold materials, oxide-based materials (e.g., silicon dioxide or spin on oxide), or low-k and ultra low-k dielectric (e.g., carbon-doped dielectrics, fluorine-doped dielectrics, porous dielectrics, and organic polymeric dielectrics). The TGVs 110 in the glass core 103 may electrically couple the first and second substrates 148-1, 148-2. As used herein, the glass core 103 with the second substrate 148-2 and/or the first substrate 148-1 may be referred to as a package substrate. TGVs 110 in glass core 103 may enable power, ground and signal connectivity to components located on either side of the glass core 103, for example, between dies 114-1, 114-2 and a circuit board 131.

The microelectronic assembly 100 may further include die 114-1 and die 114-2 electrically coupled to a top surface of the second substrate 148-2 by interconnects 150 (e.g., DTPS interconnects). In particular, conductive contacts 122 on a bottom surface of die 114-1, 114-2 may be electrically and mechanically coupled to conductive contacts 174 at a top surface of the second substrate 148-2 by interconnects 150.

Interconnects 150 may enable electrical coupling between die 114-1 and die 114-2 through conductive pathways 196 in substrate 148-2. Interconnects 150 disclosed herein may take any suitable form. In some embodiments, a set of interconnects 150 may include solder (e.g., solder bumps or balls that are subject to a thermal reflow to form the interconnects 150). Interconnects 150 that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of interconnects 150 may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression. In some embodiments, interconnects 150 disclosed herein may have a pitch between about 18 microns and 150 microns. Although FIG. 1 shows dies 114-1, 114-2 electrically coupled to substrate 148-2 by interconnects 150, dies 114-1, 114-2 may be electrically coupled by any suitable interconnects.

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked). In various embodiments, die 114 may include, or be a part of, one or more of a central processing unit (CPU), a memory device (e.g., a high-bandwidth memory device), a logic circuit, input/output circuitry, a transceiver such as a field programmable gate array transceiver, a gate array logic such as a field programmable gate array logic, of a power delivery circuitry, a III-V or a III-N device such as a III-N or III-N amplifier (e.g., GaN amplifier), Peripheral Component Interconnect Express (PCIe) circuitry, Double Data Rate (DDR) transfer circuitry, or other electronic components known in the art. In some embodiments, die 114-1 and die 114-2 may include different functionalities. As used herein, the term “functionality” with reference to a die refers to one or more functions (e.g., capability, task, operation, action, instruction execution, etc.) that the die in question can perform. For example, die 114-1 may be a CPU and die 114-2 may be a Graphics Processing Unit (GPU) or memory. In other embodiments, die 114-1 and die 114-2 may include the same or similar functionalities. For example, die 114-1 and die 114-2 may each include memory.

The microelectronic assembly 100 of FIG. 1 may also include a bridge die 202. A bridge die 202 may be at least partially within a dielectric material of the second substrate 148-2 (e.g., at least partially nested in a cavity). The bridge die 202 may be electrically coupled to dies 114 (e.g., die 114-1 and die 114-2) by interconnects 140 (e.g., DTD interconnects). In particular, conductive contacts 122 on the bottom surface of dies 114 may be electrically and mechanically coupled to the conductive contacts 124 on the top surface of the bridge die 202 by interconnects 140. In some embodiments, interconnects 140 disclosed herein may have a pitch between about 18 microns and 75 microns. A bridge die 202 may be electrically coupled to conductive pathways 196 in the second substrate 148-2 by interconnects 120. In some embodiments, interconnects 120 disclosed herein may have a pitch between about 18 microns and 75 microns. In some embodiments, as shown, interconnects 140 and interconnects 120 may include solder, and may include any of the forms described above with reference to interconnects 150. A bridge die 202 may comprise appropriate circuitry on/in a semiconductor substrate to connect at silicon-interconnect speeds with a small footprint. In some embodiments, bridge die 202 may comprise active components, such as transistors and diodes in addition to bridge circuitry including metallization traces, vias and passive components for enabling electrical coupling between two ICs; in other embodiments, bridge die 202 may include bridge circuitry including metallization traces, vias and passive components for enabling electrical coupling between die 114-1 and die 114-2, and may not include active components. In some embodiments, a bridge die 202 may be omitted.

The microelectronic assembly 100 of FIG. 1 may also include an insulating material 135 that encapsulates the die 114 (e.g., on and around die 114 and interconnects 150). The insulating material 135 may extend from a top surface of the second substrate 148-2 to a top surface of the die 114. In some embodiments, the insulating material 135 may be a dielectric material. In some embodiments, the insulating material 135 may be a mold material, such as an organic polymer with inorganic silicon oxide or aluminum oxide particles, a resin material, or an epoxy material. In some embodiments (not shown) other components, such as heat sinks may be coupled to microelectronic assembly 100 based on particular needs.

The microelectronic assembly 100 of FIG. 1 may also include an underfill material 127. In some embodiments, the underfill material 127 may extend between die 114-1, 114-2 and the second substrate 148-2 around the associated interconnects 150. In some embodiments, the underfill material 127 may be between the bottom surface of the bridge die 202 and the second substrate 148-2 (not shown). The underfill material 127 may be an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering die 114-1, 114-2 to the second substrate 148-2 when forming the interconnects 150, and then polymerizes and encapsulates the interconnects 150. The underfill process may include dispensing underfill material in liquid form, allowing the material to flow and fill the interstitial gaps around interconnects 150, and subjecting the assembly to a curing process, such as baking, to solidify the material. In some embodiments, an underfill material 127 may be omitted. Although FIG. 1 shows two separate underfill 127 portions under die 114-1 and die 114-2, the underfill 127 may be a single underfill 127 under die 114-1 and die 114-2. The underfill material 127 may be selected to have a coefficient of thermal expansion (CTE) that may mitigate or minimize the stress between die 114 and the second substrate 148-2 arising from uneven thermal expansion in the microelectronic assembly 100. In some embodiments, the CTE of the underfill material 127 may have a value that is intermediate to the CTE of the second substrate 148-2 (e.g., the CTE of the dielectric material of the substrate 148) and a CTE of the insulating material of die 114.

The microelectronic assembly 100 of FIG. 1 may also include a circuit board 131. In particular, conductive contacts 172 on a bottom surface of the first substrate 148-1 may be electrically coupled to conductive contacts 146 on a top surface of circuit board 131 by interconnects 180. Interconnects 180 disclosed herein may take any suitable form, including solder balls for a ball grid array arrangement, pins in a pin grid array arrangement or lands in a land grid array arrangement, or any of the forms described above with reference to interconnects 150. As shown in FIG. 1, in some embodiments, a set of interconnects 180 may include solder (e.g., solder bumps or balls that are subject to a thermal reflow to form the interconnects 180). In some embodiments, the interconnects 180 disclosed herein may have a pitch between about 50 microns and 300 microns. In some embodiments, an underfill material 127 may extend between the first substrate 148-1 and the circuit board 131 around the associated interconnects 180. The circuit board 131 may be a motherboard, for example, and may have other components attached to it. The circuit board may include conductive pathways and other conductive contacts for routing power, ground, and signals through the circuit board, as known in the art. In some embodiments, the interconnects 180 may not couple to a circuit board 131, but may instead couple to another IC package, an interposer, or any other suitable component.

In some embodiments, one or more levels of solder resist (e.g., epoxy liquid, liquid photoimageable dielectrics, dry film photoimageable dielectrics, acrylics, solvents) may be provided in an IC package described herein and may not be labeled or shown to avoid cluttering the drawings. Solder resist may be a liquid or dry film material including photoimageable dieletrics. In some embodiments, solder resist may be non-photoimageable.

Many of the elements of the microelectronic assembly 100 of FIG. 1 are included in other ones of the accompanying drawings; the discussion of these elements is not repeated when discussing these drawings, and any of these elements may take any of the forms disclosed herein. Further, various elements are illustrated in FIG. 1 as included in the microelectronic assembly 100, but, in various embodiments, some of these elements may not be included. For example, in various embodiments, the first substrate 148-1 and/or the second substrate 148-2, the underfill material 127, and the circuit board 131 may not be present in the microelectronic assembly 100. In some embodiments, individual ones of the microelectronic assemblies 100 disclosed herein may serve as a system-in-package (SiP) in which multiple dies 114 having different functionality are included. In such embodiments, the microelectronic assembly 100 may be referred to as an SiP.

FIG. 2 is a schematic cross-sectional view of another example microelectronic assembly 100 according to some embodiments of the present disclosure. The configuration of the embodiment shown in the figure is like that of FIG. 1, except for differences as described further. The microelectronic assembly 100 of FIG. 2 includes a glass core 103 having a first surface 190-1 and an opposite second surface 190-2, and one or more dies 114 electrically coupled to TGVs 110 in the glass core 103. The glass core 103 may provide mechanical stability to the microelectronic assembly 100 of FIG. 2, may reduce warpage, and may provide a more robust surface for attachment to a package substrate 102 or other substrate (e.g., an interposer or a circuit board).

The glass core 103 may include a cavity 129 with an opening facing the second surface 190-2 and the die 114-1 may be nested, fully or at least partially, in the cavity 129. As shown in FIG. 2, in cases where the die 114-1 is fully nested in a cavity 129, a top surface of the die 114-1 may be planar with or below the second surface 190-2 of the glass core 103. In cases where the die 114-1 is partially nested in a cavity 129, a top surface of the die 114-1 may extend above the second surface 190-2 of the glass core 103. The cavity 129 may be at least partially filled with an insulating material 133. The die 114-1 may be attached to a bottom surface of the cavity 129 by a die-attach film (DAF) 132. A DAF 132 may be any suitable material, including a non-conductive adhesive, die-attach film, a B-stage underfill, or a polymer film with adhesive property. A DAF 132 may have any suitable dimensions, for example, in some embodiments, a DAF 132 may have a thickness (e.g., height or z-height) between 5 microns and 10 microns.

The die 114-1 may be coupled to the dies 114-2, 114-3 in a layer above the die 114-1 through the interconnects 140. The interconnects 140 may be disposed between some of the conductive contacts 122 at the bottom of the dies 114-2, 114-3 and some of the conductive contacts 124 at the top of the die 114-1. Some other conductive contacts 122 at the bottom of the dies 114-2 and/or 114-3 may further couple one or more of the dies 114-2, 114-3 to the glass core 103 by glass core-to-die (GCTD) interconnects 142. The GCTD interconnects 142 may be disposed between some of the conductive contacts 122 at the bottom of the dies 114-2, 114-3 and some of the conductive contacts 128 at the top of the glass core 103. The GCTD interconnects 142 may be similar to the interconnects 150, described above. In some embodiments, the underfill material 127 may extend between different ones of the dies 114 around the associated interconnects 140 and/or GCTD interconnects 142. In some embodiments, a die 114-2 and/or a die 114-3 may be embedded in an insulating material 133. In some embodiments, an overall thickness (e.g., a z-height) of the insulating material 133 may be between 200 microns and 800 microns (e.g., substantially equal to a thickness of die 114-2 or 114-3 and the underfill material 127). In some embodiments, the insulating material 133 may form multiple layers (e.g., a dielectric material formed in multiple layers, as known in the art) and may embed one or more dies 114 in a layer. In some embodiments, the insulating material 133 may be a dielectric material, such as an organic dielectric material, a fire retardant grade 4 material (FR-4), BT resin, polyimide materials, glass reinforced epoxy matrix materials, or low-k and ultra low-k dielectric (e.g., carbon-doped dielectrics, fluorine-doped dielectrics, porous dielectrics, and organic polymeric dielectrics). In some embodiments, the insulating material 133 may be a mold material, such as an organic polymer with inorganic silica particles.

As shown in FIG. 2, the glass core 103 may further include conductive contacts 126 at the bottom of the glass core 103, and TGVs 110 may extend between and electrically couple conductive contacts 126 at the bottom of the glass core 103 and conductive contacts 128 at the top of the glass core 103. The conductive contacts 126, 128 may be similar to other conductive contacts disclosed herein (e.g., the conductive contacts 122, 124, 144, and/or 146), and may include bond pads, solder bumps, conductive posts, or any other suitable conductive contact, for example. As shown in FIG. 2, in some embodiments, at least some of the TGVs 110 may have an hourglass shape. For example, at least some of the TGVs 110 may has a first width at the first surface 190-1 of the glass core 103 (e.g., at the bottom surface of the glass core 103), a second width at the second surface 190-2 of the glass core 103 (e.g., at the top surface of the glass core 103), and a third width between the first surface 190-1 and the second surface 190-2 of the glass core 103, where the third width is smaller than the first width and the second width.

The dies 114-2, 114-3 may be electrically coupled to the package substrate 102 through the TGVs 110 and glass core-to-package substrate (GCTPS) interconnects 152, which may be power delivery interconnects or high-speed signal interconnects. The GCTPS interconnects 152 may be similar to the interconnects 180, described above. The top surface of the package substrate 102 may include a set of conductive contacts 246, the glass core 103 may include a set of conductive contacts 126 on the first surface 190-1, and the GCTPS interconnects 152 may be between, and couple the conductive contacts 246 with corresponding ones of the conductive contacts 126. In some embodiments, the underfill material 127 may extend between the glass core 103 and the package substrate 102 around the associated GCTPS interconnects 152.

The package substrate 102 may include an insulating material (e.g., a dielectric material formed in multiple layers, as known in the art) and one or more conductive pathways to route power, ground, and signals through the dielectric material (e.g., including conductive traces and/or conductive vias, as shown). In some embodiments, the insulating material of the package substrate 102 may be a dielectric material, such as an organic dielectric material, a fire retardant grade 4 material (FR-4), bismaleimide triazine (BT) resin, polyimide materials, glass reinforced epoxy matrix materials, organic dielectrics with inorganic fillers or low-k and ultra low-k dielectric (e.g., carbon-doped dielectrics, fluorine-doped dielectrics, porous dielectrics, and organic polymeric dielectrics). In particular, when the package substrate 102 is formed using standard PCB processes, the package substrate 102 may include FR-4, and the conductive pathways in the package substrate 102 may be formed by patterned sheets of copper separated by build-up layers of the FR-4. The conductive pathways in the package substrate 102 may be bordered by liner materials, such as adhesion liners and/or barrier liners, as suitable. In some embodiments, the package substrate 102 may be formed using a lithographically defined via packaging process. In some embodiments, the package substrate 102 may be manufactured using standard organic package manufacturing processes, and thus the package substrate 102 may take the form of an organic package. In some embodiments, the package substrate 102 may be a set of redistribution layers formed on a panel carrier by laminating or spinning on a dielectric material, and creating conductive vias and lines by laser drilling and plating. In some embodiments, the package substrate 102 may be formed on a removable carrier using any suitable technique, such as a redistribution layer technique. Any method known in the art for fabrication of the package substrate 102 may be used, and for the sake of brevity, such methods will not be discussed in further detail herein.

The glass core 103 included in a microelectronic assembly 100 as described with reference to FIG. 1 or FIG. 2 or included in any other microelectronic assembly or device, may be subject to TGV stress prior to inclusion in the microelectronic assembly 100. For example, FIG. 3 illustrates surfaces of a glass core 103 from which TGV stress may initiate, according to some embodiments of the present disclosure. As shown in FIG. 3, a glass core 103 may have a first surface 190-1 and an opposing second surface 190-2, e.g., bottom and top surfaces when the glass core 103 is included in a microelectronic assembly 100 (where, together, the first and second surfaces 190-1, 190-2 may be referred to as “faces 190”). The glass core 103 may also include a side 190-3, which is a surface of the glass core 103 that may be referred to as an edge or a sidewall of the glass core 103, i.e., a surface that extends between the first surface 190-1 and the second surface 190-2. As further shown in FIG. 3, TGV openings 192 may be formed in the glass core 103, extending between the first surface 190-1 and the second surface 190-2. A sidewall 190-4 may then refer to one or more sidewalls of the TGV openings 192. When a conductive material is deposited in the TGV openings 192, TGV stress may initiate from the sidewall 190-4 due to CTE mismatch between the glass material of the glass core 103 and the conductive material in the TGV openings 192.

FIGS. 4A-4D are simplified schematic side, cross-sectional views of example portions of a microelectronic assembly according to some embodiments of the present disclosure. FIG. 4A illustrates an example portion 400A including a glass core 103 with hourglass shaped TGV openings 192 extending from the first surface 190-1 to the second surface 190-2 of the glass core 103 and having a photopolymer liner 422 on a sidewall 190-4 in the TGV openings 192. As used herein, an hourglass shaped TGV 110 has a first diameter (e.g., xy-dimension) at a first surface 190-1, a second diameter at a second surface 190-2, a third diameter between the first diameter and the second diameter, and the third diameter is smaller than the first diameter and the second diameter. The photopolymer liner 422 may include any suitable material that may separate the glass materials of the glass core 103 at the sidewalls 190-4 of the TGV openings 192 and the conductive bulk fill material that will later be deposited in the TGV openings 192, to help buffer the glass surface at the sidewalls of the TGV openings 192, and to resist tensile stresses, e.g., caused by the contraction of the metals subsequently filled into the TGV openings 192. In some embodiments, a material of the photopolymer liner 422 may include a polyurethane acrylate, an acrylic, a methacrylic polymer, a polyvinyl alcohol, a polyvinyl cinnamate, a polyisoprene, a polyamide, an epoxy, a polyimide, styrenic block copolymers, or a nitrile rubber. The photopolymer liner 422 may have any suitable dimensions to function as a buffer between the glass core 103 and the conductive bulk fill material of the TGVs 110 (e.g., as shown in FIG. 6F), and may depend on a diameter of the TGV openings 192. In some embodiments, the photopolymer liner 422 may have a width (e.g., y-dimension) between about 500 nanometers and 10 microns, (e.g., between about 1 micron and about 6 microns, or between about 4 microns and about 8 microns). In some embodiments, a width of the photopolymer liner 422 may vary along a height (e.g., z-dimension). A width 192-2A, 192-2B, of the photopolymer liner 422 adjacent to a top surface 190-2 and a width 192-1A, 192-1B of the photopolymer liner 422 adjacent to a bottom surface 190-1 of the glass core 103 may be greater than a width 193A, 193B of the photopolymer liner 422 at a middle of the glass core 103. Although FIG. 4A illustrates a photopolymer liner 422 having a width that varies along a height of the TGV opening 192, in some embodiments, the photopolymer liner 422 may have a width that is substantially equal along a height of the TGV opening 192 (e.g., conformally follows the shape of the TGV opening 192, as shown in FIG. 4C).

FIG. 4B illustrates an example portion 400B including a glass core 103 with V-shaped TGV openings 192 extending from the first surface 190-1 to the second surface 190-2 of the glass core 103 and having a photopolymer liner 422 on a sidewall 190-4 in the TGV openings 192. As used herein, a V-shaped TGV opening 192 is tapered with a first diameter (e.g., xy-dimension) at a first surface 190-1, a second diameter at a second surface 190-2, and the first diameter is smaller than the second diameter. In some embodiments, a V-shaped TGV opening 192 may be inverted such that the second diameter is at the first surface 190-1 and the first diameter is at the second surface 190-2. The photopolymer liner 422 may include any suitable material and any suitable dimensions, as described above with reference to FIG. 4A. As shown in FIG. 4B, a width of the photopolymer liner 422 may vary along a height (e.g., z-dimension), where a width 195A, 195B, of the photopolymer liner 422 is wider at one surface (e.g., second surface 190-2) having a greater diameter and a width 194A, 194B of the photopolymer liner 422 is narrower at the opposite surface (e.g., first surface 190-1) having a smaller diameter. Although FIG. 4B illustrates a photopolymer liner 422 having a width that varies along a height of the TGV opening 192, in some embodiments, the photopolymer liner 422 may have a width that is substantially equal along a height of the TGV opening 192 (e.g., conformally follows the shape of the TGV opening 192, as shown in FIG. 4C).

FIG. 4C illustrates an example portion 400C including a glass core 103 with TGV openings 192 extending from the first surface 190-1 to the second surface 190-2 of the glass core 103 and having a photopolymer liner 422 on a straight sidewall 190-4 in the TGV openings 192. As used herein, a TGV opening 192 with straight sidewalls 190-4 has a diameter (e.g., xy-dimension) that is substantially the same from a first surface 190-1 to a second surface 190-2. The photopolymer liner 422 may include any suitable material and any suitable dimensions, as described above with reference to FIG. 4A. As shown in FIG. 4C, a width 196A, 196B of the photopolymer liner 422 may be substantially equal along a height (e.g., z-dimension).

FIG. 4D illustrates a simplified schematic side, cross-sectional view of another example portion of a microelectronic assembly according to some embodiments of the present disclosure. The configuration of the embodiment shown in the figure is like that of FIG. 4C, except for differences as described further. In particular, FIG. 4D illustrates an embodiment 400D where a photopolymer liner 422 includes a first region 422A having a first width 197A and a second region 422B having a second width 197B that is less than the first width 197A. In some embodiments, the first width 197A and the second width 197B of the photopolymer liner 422 may have different dimensions due to misalignment of a mask (e.g., photomask 604 in FIG. 6B) during formation of the photopolymer liner 422 on the sidewall 190-4 of the TGV openings 192. In such embodiments, the photopolymer liner 422 may be identifiable by its material composition as a crosslinked polymer (e.g., using XPS, FTIR, or Raman Spectroscopy, as described above) and by the alignment offsets that form a photopolymer liner 422 with a first region (e.g., 422A) having a first width 197A and a second region (e.g., 422B) having a second width 197B that is less than the first width 197A. Although FIG. 4D illustrates the second width 197B as less than the first width 197A, in some embodiments, a first width 197A may be less than a second width 197B.

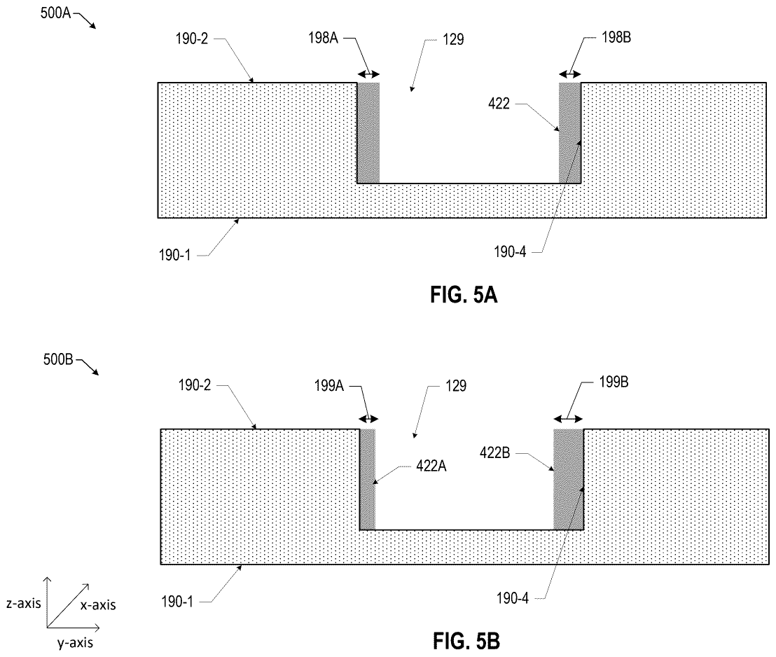

FIG. 5A is a simplified schematic side, cross-sectional view of an example portion of a microelectronic assembly according to some embodiments of the present disclosure. FIG. 5A illustrates an example portion 500A including a glass core 103 with a cavity 129 extending from the second surface 190-2 of the glass core 103 and having a photopolymer liner 422 on straight sidewalls 190-4 in the cavity 129. The photopolymer liner 422 may include any suitable material and any suitable dimensions, as described above with reference to FIG. 4A. As shown in FIG. 5A, a width 198A, 198B (e.g., y-dimension) of the photopolymer liner 422 may be substantially equal along a height (e.g., z-dimension). Further, as shown in FIG. 5A, a width 198A of the photopolymer liner 422 may be substantially equal to a width 198B of the photopolymer liner 422.

FIG. 5B illustrates a simplified schematic side, cross-sectional view of another example portion of a microelectronic assembly according to some embodiments of the present disclosure. The configuration of the embodiment shown in the figure is like that of FIG. 5A, except for differences as described further. In particular, FIG. 5B illustrates an embodiment 500B where a glass core 103 with a cavity 129 and a photopolymer liner 422 including a first region 422A having a first width 199A and a second region 422B having a second width 199B, where the second width 199B is greater than the first width 199A. In some embodiments, the first width 199A and the second width 199B of the photopolymer liner 422 may have different dimensions due to misalignment of a mask (e.g., photomask 604 in FIG. 6B) during formation of the photopolymer liner 422 on the sidewalls 190-4 of the cavity 129. In such embodiments, the photopolymer liner 422 may be identifiable by its material composition as a crosslinked polymer (e.g., using XPS, FTIR, or Raman Spectroscopy, as described above) and by the alignment offsets that form a photopolymer liner 422 with a first region 422A having a first width 199A and a second region 422B having a second width 199B that is greater than the first width 199A. Although FIG. 5B illustrates the second width 199B as greater than the first width 199A, in some embodiments, a first width 199A may be greater than a second width 199B.

A technique involving the use of a photopolymer liner for TGV stress alleviation as described herein may be applied to reduce TGV stress before including the glass core 103 in a microelectronic assembly 100. Any suitable techniques may be used to manufacture the microelectronic assemblies 100 disclosed herein. For example, FIGS. 6A-6F are side, cross-sectional views of various stages in an example process for manufacturing an example glass core 103 with a photopolymer liner 422 (e.g., as shown in FIG. 4A and similar to a photopolymer liner 422 as shown in FIGS. 4B, 4C, and 5) in a microelectronic assembly 100, in accordance with various embodiments. Although the operations discussed below with reference to FIGS. 6A-6F (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 6A-6F may be modified in accordance with the present disclosure to fabricate others of microelectronic assembly 100 disclosed herein.

FIG. 6A illustrates an assembly including a glass core 103 having a first surface 190-1 and a second surface 190-2, and TGV openings 192. The glass core 103 may have any suitable dimensions, for example, the glass core 103 may include a full panel glass core having a surface area of approximately 500 millimeters by 500 millimeters (e.g., xy-dimension), or may include a quarter panel glass core having a surface area of approximately 250 millimeters by 250 millimeters. In some embodiments, a glass core 103 may have a surface area of between approximately 10 millimeters by 10 millimeters and approximately 240 millimeters by 240 millimeters. Furthermore, although two TGV openings 192 are shown in FIG. 6A as well as in FIGS. 6B-6F, in other embodiments, the microelectronic assemblies described herein may include any number of one or more TGV openings 192. Although the two TGV openings 192 have an hourglass shape, the TGV openings 192 may have any suitable shape, including, for example, sides that taper to form a V-shape, as shown in FIG. 4B, sides that are straight to form a cylindrical or rectangular shape, as shown in FIG. 4C, or a cavity, as shown in FIG. 5A. The TGV openings 192 may further include blind vias, where the TGV opening does only partially through the glass core 103 and does not extend from the first surface 190-1 to the second surface 190-2 (e.g., similar to a narrow cavity). In various embodiments, the TGV openings 192 may be formed in the glass core 103 using any suitable subtractive technique such as direct laser drilling or laser-induced etching process, possibly in combination with any suitable patterning technique such as photolithographic or electron-beam (e-beam) patterning. In other embodiments, the TGV openings 192 may be formed during fabrication of the glass core 103 itself, e.g., when molten glass is filled into a mold that has space for the future TGV openings 192.

FIG. 6B illustrates an assembly including a bath 601 filled with a photo-curable polymer solution 602, a photomask 604 with UV exposure openings 603, and a UV light source 613. The UV exposure openings 603 in the photomask 604 will expose those portions of the photo-curable polymer solution 602 to the UV light source 613 causing selective crosslinking of the photo-curable polymer solution 602, and will not expose the other portions covered by the photomask 604 to the UV light source 613. In some embodiments, the UV exposure openings 603 in the photomask 604 may be shaped to conform with a perimeter of the TGV openings 192 (e.g., a TGV opening 192 with a cylindrical shape, V-shape, or an hourglass shape may have an UV exposure opening 603 in the photomask 604 that is donut-shaped). In some embodiments, the UV exposure openings 603 in the photomask 604 may align and may be sized to match with the TGV openings 192. In some embodiments, the size and shape of the UV exposure openings 603 may determine a width (e.g., y-dimension) of a photopolymer liner 422. The photo-curable polymer solution 602 may include a negative-tone polymer solution.

FIG. 6C illustrates an assembly after immersing the assembly of FIG. 6A in the assembly of FIG. 6B, aligning the TGV openings 192 with the UV exposure openings 603 in the photomask 604, and exposing the assembly to the UV light source 613. The assembly of FIG. 6C further illustrates a backing plate 606 that may be used to press the glass core 103 into a bottom surface of the bath 601 and remove any excess photo-curable polymer solution 602 from between the first surface 190-1 of the glass core 103 and the bottom of the bath 601 to reduce the occurrence, or prevent the occurrence, of any trapped solution from crosslinking and causing the glass core 103 to stick to the bottom of the bath 601, or of having excess crosslinked photopolymer attached thereto.

In some embodiments, a protective coating (not shown), such as a foam, a soft rubber, a compressible polymer, a hydrophobic coating, or a fluorinated coating, may be deposited on the first surface 190-1 and/or the second surface 190-2 of the glass core 103 to reduce and/or prevent the attachment of excess photopolymer on the first surface 190-1 and/or the second surface 190-2 of the glass core 103. The protective coating may be removed prior to performing further operations on the glass core 103 with the photopolymer liner 422 to incorporate into a microelectronic assembly.

In some embodiments (e.g., in embodiments that include a negative-tone polymer solution), the TGV openings 192 in the photo-curable polymer solution 602 may be exposed to the UV light source 613 and may form a crosslinked polymer plug that, subsequently, may be opened using any suitable technique, such as laser drilling, leaving a photopolymer liner 422. In other embodiments, a positive tone (e.g., solid) polymeric film may be laminated in the TGV openings 192, and a center portion of the positive tone polymeric film may be exposed to UV light to develop out the center portion, leaving a photopolymer liner 422.

FIG. 6D illustrates an assembly after the assembly of FIG. 6C is selectively exposed to the UV light source 613 through the UV exposure openings 603 in the photomask 604 and crosslinks are formed in the exposed portions of the photo-curable polymer solution 602 to create a photopolymer liner 422 in the TGV openings 192.

FIG. 6E illustrates an assembly subsequent to removing from the bath 601 and washing away any residual photo-curable polymer solution 602. The assembly of FIG. 6E includes a glass core 103 with TGV openings 192 having a photopolymer liner 422. The assembly of FIG. 6E may undergo an additional curing process, such as exposure to heat and/or UV light, to further crosslink the photopolymer liner 422. The photopolymer liner 422 may include any suitable material and may have any suitable dimensions, as described above with reference to FIG. 4A.

FIG. 6F illustrates an assembly subsequent to depositing a conductive bulk fill material in the TGV openings 192 lined with the photopolymer liner 422 to form TGVs 110. The TGV openings 192 filled with conductive materials are one example of any of the TGVs 110, described herein. The conductive bulk fill material of the TGVs 110 may include any suitable conductive material, e.g., any of the materials described above with reference to FIG. 1. The conductive bulk fill material may be deposited using any suitable deposition technique such as electroplating, ALD, CVD, PVD, or a conductive paste.

Various embodiments of TGVs with a photopolymer liner, described above may, advantageously, be easily fabricated in parallel with conventional manufacturing techniques for glass core substrates. Various arrangements of the microelectronic assemblies 100 and glass cores 103 as shown in FIGS. 1-5 do not represent an exhaustive set of microelectronic assemblies and glass cores in which one or more TGVs with a photopolymer liner as described herein may be implemented, but merely provide some illustrative examples. In particular, the number and positions of various elements shown in FIGS. 1-5 is purely illustrative and, in various other embodiments, other numbers of these elements, provided in other locations relative to one another may be used in accordance with the general architecture considerations described herein. For example, although not specifically shown in the present drawings, in some embodiments, a microelectronic assembly 100 may include a redistribution layer (RDL) between any pair of layers shown in FIG. 1 and FIG. 2, the RDL including a plurality of interconnect structures (e.g., conductive lines and conductive vias) to assist routing of signals and/or power between components. In yet another example, features of any one of FIGS. 1-5 may be combined with features of any other one of FIGS. 1-5. For example, in some embodiments, some portions of a glass core 103 may include one or more TGVs 110 with a photopolymer liner, while other portions of a glass core 103 may include TGVs 110 without the photopolymer liner.

Although FIGS. 6A-6F illustrate fabricating a glass core 103 having a TGV 110 with a photopolymer liner 422, the operations described may be used to fabricate any features in a glass core 103 that are openings lined with a photopolymer liner 422 including, for example, a cavity (e.g., cavity 129, as shown in FIG. 5A).

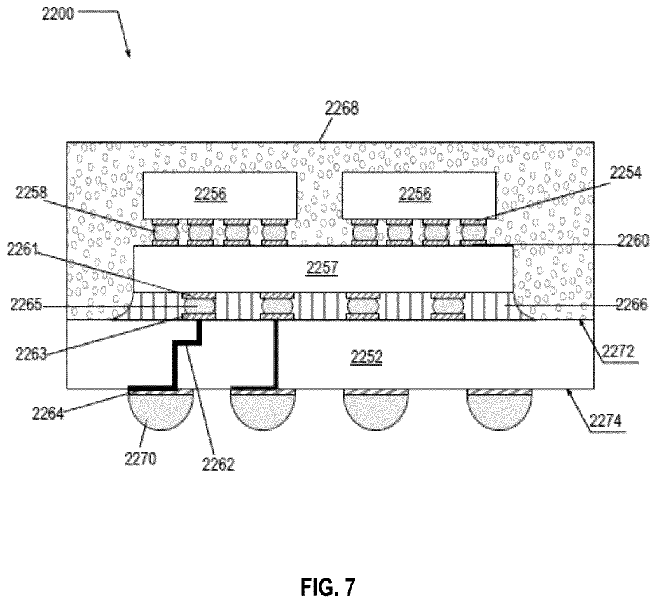

The packages disclosed herein, e.g., any of the microelectronic assemblies 100, or any further embodiments described herein, may be included in any suitable electronic component. FIGS. 7-9 illustrate various examples of packages, assemblies, and devices that may be used with or include any of the IC packages as disclosed herein.

FIG. 7 is a side, cross-sectional view of an example IC package 2200 that may include microelectronic assemblies in accordance with any of the embodiments disclosed herein. In some embodiments, the IC package 2200 may be a system-in-package (SiP).

As shown in FIG. 7, package support 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures including lines and/or vias, e.g., as discussed above with reference to FIG. 1.

Package support 2252 may include conductive contacts 2263 that are coupled to conductive pathway 2262 through package support 2252, allowing circuitry within dies 2256 and/or interposer 2257 to electrically couple to various ones of conductive contacts 2264 (or to other devices included in package support 2252, not shown).

IC package 2200 may include interposer 2257 coupled to package support 2252 via conductive contacts 2261 of interposer 2257, first level interconnects (FLI) 2265, and conductive contacts 2263 of package support 2252. FLI 2265 illustrated in FIG. 7 are solder bumps, but any suitable FLI 2265 may be used, such as solder bumps, solder posts, or bond wires.

IC package 2200 may include one or more dies 2256 coupled to interposer 2257 via conductive contacts 2254 of dies 2256, FLI 2258, and conductive contacts 2260 of interposer 2257. In various embodiments, interposer 2257 may include glass core 103 including glass as described herein. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). FLI 2258 illustrated in FIG. 7 are solder bumps, but any suitable FLI 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, underfill material 2266 may be disposed between package support 2252 and interposer 2257 around FLI 2265, and mold 2268 may be disposed around dies 2256 and interposer 2257 and in contact with package support 2252. In some embodiments, underfill material 2266 may be the same as mold 2268. Example materials that may be used for underfill material 2266 and mold 2268 are epoxies as suitable. Second level interconnects (SLI) 2270 may be coupled to conductive contacts 2264. SLI 2270 illustrated in FIG. 7 are solder balls (e.g., for a ball grid array (BGA) arrangement), but any suitable SLI 2270 may be used (e.g., pins in a pin grid array arrangement or lands in a land grid array arrangement). SLI 2270 may be used to couple IC package 2200 to another component, such as a circuit board (e.g., a motherboard), an interposer, or another IC package, as known in the art and as discussed below with reference to FIG. 9.

In embodiments in which IC package 2200 includes multiple dies 2256, IC package 2200 may be referred to as a multichip package (MCP). Dies 2256 may include circuitry to perform any desired functionality. For example, besides one or more of dies 2256 including components of dies 114 as described herein, one or more of dies 2256 may be logic dies (e.g., silicon-based dies), one or more of dies 2256 may be memory dies (e.g., high-bandwidth memory), etc. In some embodiments, at least some of dies 2256 may not include components of dies 114 as described herein.

Although IC package 2200 illustrated in FIG. 7 is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package support 2252, or on either face of interposer 2257. More generally, IC package 2200 may include any other active or passive components known in the art.

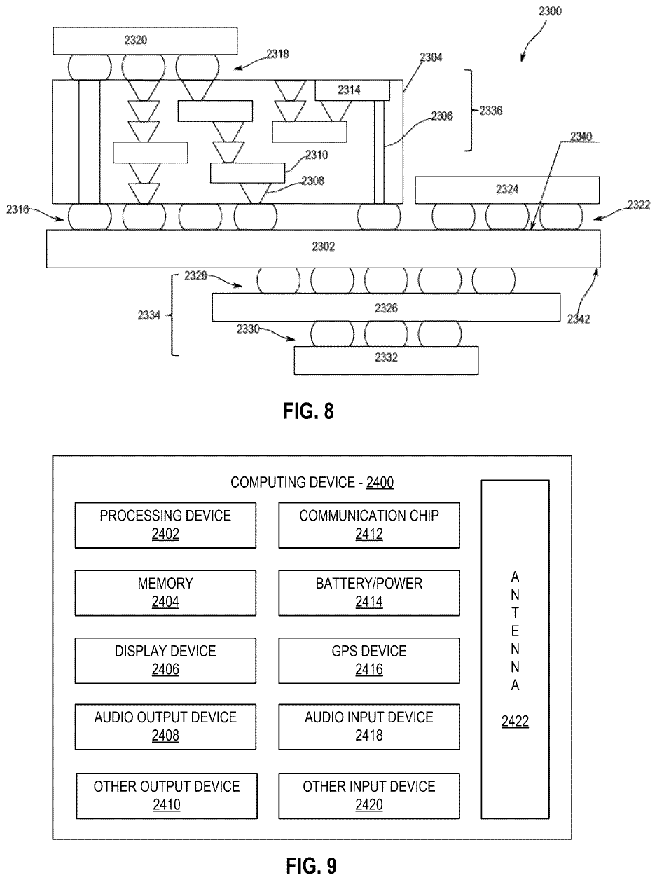

FIG. 8 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 7.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package support.

FIG. 8 illustrates that, in some embodiments, IC device assembly 2300 may include a package-on-interposer structure 2336 coupled to first face 2340 of circuit board 2302 by coupling components 2316. Although not shown so as not to clutter the drawing, package-on-interposer structure 2336 may include a glass core 103, such as glass layer, in some embodiments. In other embodiments, package-on-interposer structure 2336 may not include a core. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. In some embodiments, IC package 2320 may include microelectronic assembly 100, and other components as described herein, which are not shown so as not to clutter the drawing. Coupling components 2318 may take any suitable form depending on desired functionalities, such as the forms discussed above with reference to coupling components 2316. In some embodiments, IC package 2320 may be or include IC package 2200, e.g., as described above with reference to FIG. 7.

Although a single IC package 2320 is shown in FIG. 8, multiple IC packages may be coupled to interposer 2304; indeed, additional interposers may be coupled to interposer 2304. Interposer 2304 may provide an intervening package support used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in FIG. 8, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2310 and vias 2308, including TSVs 2306. Interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

FIG. 9 is a block diagram of an example computing device 2400 that may include one or more components having one or more IC packages in accordance with any of the embodiments disclosed herein. For example, any suitable ones of the components of computing device 2400 may include microelectronic assembly 100 including glass in accordance with any of the embodiments disclosed herein. In another example, any one or more of the components of computing device 2400 may include any embodiments of IC package 2200 (e.g., as shown in FIG. 7). In yet another example, any one or more of the components of computing device 2400 may include an IC device assembly 2300 (e.g., as shown in FIG. 8).

A number of components are illustrated in FIG. 9 as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in FIG. 9, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more digital signal processors (DSPs), ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips; note that the terms “chip,” “die,” and “IC die” are used interchangeably herein). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives of it, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

The following paragraphs provide various examples of the embodiments disclosed herein.

Example 1 provides a microelectronic assembly, including a glass core having a first surface and an opposing second surface; a through-glass via (TGV) extending between the first surface and the second surface of the glass core, where the TGV includes a conductive material; and a liner material between the glass core and the conductive material of the TGV, where the liner material includes a photopolymer.

Example 2 provides the microelectronic assembly of example 1, where the TGV is tapered, and where a volume of the conductive material of the TGV is consistent along a height of the TGV, and a width of the liner material varies along the height of the TGV.

Example 3 provides the microelectronic assembly of example 2, where the TGV is V-shaped having a greater diameter at the second surface and a smaller diameter at the first surface.

Example 4 provides the microelectronic assembly of example 3, where the width of the liner material is greater at the second surface and is smaller at the first surface.

Example 5 provides the microelectronic assembly of any one of examples 2-4, where the TGV is hourglass shaped having a first diameter at the first surface, a second diameter at the second surface, and a third diameter at a plane parallel to and between the first surface and the second surface, and where the first diameter and the second diameter are greater than the third diameter.

Example 6 provides the microelectronic assembly of example 5, where the width of the liner material is greater at the first surface and the second surface and is smaller at the plane between the first surface and the second surface.

Example 7 provides the microelectronic assembly of example 1, where a width of the liner material is between 500 nanometers and 10 microns.

Example 8 provides the microelectronic assembly of example 1, where a thickness of the glass core is between 50 microns and 2 millimeters.

Example 9 provides the microelectronic assembly of example 1, where the photopolymer includes a polyurethane acrylate, an acrylic, a methacrylic polymer, a polyvinyl alcohol, a polyvinyl cinnamate, a polyisoprene, a polyamide, an epoxy, a polyimide, styrenic block copolymers, or a nitrile rubber.

Example 10 provides the microelectronic assembly of example 1, where the conductive material of the TGV includes copper, silver, nickel, gold, aluminum, or alloys thereof.

Example 11 provides the microelectronic assembly of example 1, where the TGV is one of a plurality of TGVs, and the microelectronic assembly further including a first substrate on the first surface of the glass core, the first substrate including first conductive pathways through a first dielectric material electrically coupled to at least one of the plurality of TGVs; and a second substrate on the second surface of the glass core, the second substrate including second conductive pathways through a second dielectric material electrically coupled to at least one of the plurality of TGVs.

Example 12 provides the microelectronic assembly of example 11, further including a die on the second substrate and electrically coupled to one or more of the second conductive pathways in the second substrate.

Example 13 provides the microelectronic assembly of example 12, further including an interconnect die at least partially within the second dielectric material of the second substrate and electrically coupled to the die.

Example 14 provides the microelectronic assembly of example 12 or 13, further including an insulating material surrounding the die.

Example 15 provides the microelectronic assembly of any one of examples 11-14, further including a circuit board at the first substrate and electrically coupled to one or more of the first conductive pathways.

Example 16 provides a microelectronic assembly, including a glass layer having a surface; a cavity in the surface of the glass layer, the cavity having sidewalls; and a liner material on the sidewalls of the cavity, where the liner material includes a photopolymer.

Example 17 provides the microelectronic assembly of example 16, where a width of the liner material is between 500 nanometers and 10 microns.

Example 18 provides the microelectronic assembly of example 16 or 17, where the photopolymer includes a polyurethane acrylate, an acrylic, a methacrylic polymer, a polyvinyl alcohol, a polyvinyl cinnamate, a polyisoprene, a polyamide, an epoxy, a polyimide, styrenic block copolymers, or a nitrile rubber.

Example 19 provides the microelectronic assembly of any one of examples 16-18, further including a die at least partially embedded in the cavity.

Example 20 provides the microelectronic assembly of example 19, further including an insulating material in the cavity surrounding the die.

Example 21 provides the microelectronic assembly of any one of examples 16-20, where a thickness of the glass layer is between 50 microns and 2 millimeters.

Example 22 provides the microelectronic assembly of any one of examples 16-21, where the surface of the glass layer is a second surface, and the glass layer further including a first surface opposite the second surface, and the microelectronic assembly further including a through-glass via (TGV) extending between the first surface and the second surface of the glass layer, where the TGV includes a conductive material, and where the liner material is between the glass layer and the conductive material of the TGV.

Example 23 provides the microelectronic assembly of example 22, further including a first die at least partially embedded in the cavity; and a second die on the second surface of the glass layer and electrically coupled to the first die.

Example 24 provides the microelectronic assembly of example 23, where the second die is further electrically coupled to the TGV.

Example 25 provides the microelectronic assembly of any one of examples 22-24, further including a circuit board at the first surface of the glass layer and electrically coupled to the TGV.

Example 26 provides a microelectronic assembly, including a glass core having a first surface and an opposing second surface, the glass core including an opening in the second surface and the opening including a sidewall; and a liner material on the sidewall of the opening in the glass core, where the liner material includes a first region having a first width and a second region having a second width less than the first width, and where the liner material includes a crosslinked polymer.

Example 27 provides the microelectronic assembly of example 26, where the first width of the liner material is between 500 nanometers and 10 microns.

Example 28 provides the microelectronic assembly of example 26 or 27, where the second width of the liner material is between 500 nanometers and 10 microns.

Example 29 provides the microelectronic assembly of any one of examples 26-28, where the crosslinked polymer includes a polyurethane acrylate, an acrylic, a methacrylic polymer, a polyvinyl alcohol, a polyvinyl cinnamate, a polyisoprene, a polyamide, an epoxy, a polyimide, styrenic block copolymers, or a nitrile rubber.

Example 30 provides the microelectronic assembly of any one of examples 26-29, where the opening in the glass core includes a through-glass via (TGV).

Example 31 provides the microelectronic assembly of example 30, further including a conductive material in the TGV, where the liner material is between the glass core and the conductive material.

Example 32 provides the microelectronic assembly of any one of examples 26-31, where the opening in the glass core includes a cavity.

Example 33 provides the microelectronic assembly of example 32, further including a die at least partially embedded in the cavity.

Example 34 provides a method of manufacturing a microelectronic assembly, including immersing a glass core, having a via opening with a sidewall, in a photo-curable polymer solution; and selectively exposing the glass core in the photo-curable polymer solution to an ultraviolet (UV) light source to form a liner material on the sidewall of the via opening, where the liner material includes a photopolymer.

Example 35 provides the method of example 34, where the liner material has a width between 500 nanometers and 10 microns.

Example 36 provides the method of example 34 or 35, further including removing the glass core having the via opening with the liner material on the sidewall from the photo-curable polymer solution; and washing away any residual photo-curable polymer solution.

Example 37 provides the method of example 36, further including performing a second curing process on the glass core having the via opening with the liner material on the sidewall, where the second curing process includes exposure to heat or UV light.

Example 38 provides the method of example 36 or 37, further including depositing a conductive material in the via opening to form a conductive via, where the liner material is between the glass core and the conductive material.

Example 39 provides the method of example 38, where the glass core includes a first surface and an opposing second surface, and the conductive via and the liner material extend between the first surface and the second surface of the glass core, and the method further including forming a first dielectric on the first surface of the glass core, the first dielectric including a first conductive pathway; electrically coupling the first conductive pathway to the conductive via; forming a second dielectric on the second surface of the glass core, the second dielectric including a second conductive pathway; and electrically coupling the second conductive pathway to the conductive via.

Example 40 provides the method of example 39, further including attaching a die on the second dielectric; and electrically coupling the die to the second conductive pathway in the second dielectric.

Example 41 provides the method of example 39 or 40, further including electrically coupling a circuit board to the first conductive pathway in the first dielectric.

1. A microelectronic assembly, comprising:
a glass core having a first surface and an opposing second surface;
a through-glass via (TGV) extending between the first surface and the second surface of the glass core, wherein the TGV includes a conductive material; and
a liner material between the glass core and the conductive material of the TGV, wherein the liner material includes a photopolymer.

2. The microelectronic assembly of claim 1, wherein the TGV is tapered, and wherein a volume of the conductive material of the TGV is consistent along a height of the TGV, and a width of the liner material varies along the height of the TGV.

3. The microelectronic assembly of claim 2, wherein the TGV is V-shaped having a greater diameter at the second surface and a smaller diameter at the first surface.

4. The microelectronic assembly of claim 3, wherein the width of the liner material is greater at the second surface and is smaller at the first surface.

5. The microelectronic assembly of claim 2, wherein the TGV is hourglass shaped having a first diameter at the first surface, a second diameter at the second surface, and a third diameter at a plane parallel to and between the first surface and the second surface, and wherein the first diameter and the second diameter are greater than the third diameter.

6. The microelectronic assembly of claim 5, wherein the width of the liner material is greater at the first surface and the second surface and is smaller at the plane between the first surface and the second surface.

7. The microelectronic assembly of claim 1, wherein a width of the liner material is between 500 nanometers and 10 microns.

8. The microelectronic assembly of claim 1, wherein a thickness of the glass core is between 50 microns and 2 millimeters.

9. The microelectronic assembly of claim 1, wherein the photopolymer includes a polyurethane acrylate, an acrylic, a methacrylic polymer, a polyvinyl alcohol, a polyvinyl cinnamate, a polyisoprene, a polyamide, an epoxy, a polyimide, styrenic block copolymers, or a nitrile rubber.

10. The microelectronic assembly of claim 1, wherein the conductive material of the TGV includes copper, silver, nickel, gold, aluminum, or alloys thereof.

11. The microelectronic assembly of claim 1, wherein the TGV is one of a plurality of TGVs, and the microelectronic assembly further comprising:
a first substrate on the first surface of the glass core, the first substrate including first conductive pathways through a first dielectric material electrically coupled to at least one of the plurality of TGVs; and
a second substrate on the second surface of the glass core, the second substrate including second conductive pathways through a second dielectric material electrically coupled to at least one of the plurality of TGVs.

12. A microelectronic assembly, comprising:
a glass layer having a surface;
a cavity in the surface of the glass layer, the cavity having sidewalls; and
a liner material on the sidewalls of the cavity, wherein the liner material includes a photopolymer.

13. The microelectronic assembly of claim 12, wherein a width of the liner material is between 500 nanometers and 10 microns.

14. The microelectronic assembly of claim 12, wherein the photopolymer includes a polyurethane acrylate, an acrylic, a methacrylic polymer, a polyvinyl alcohol, a polyvinyl cinnamate, a polyisoprene, a polyamide, an epoxy, a polyimide, styrenic block copolymers, or a nitrile rubber.

15. The microelectronic assembly of claim 12, wherein the surface of the glass layer is a second surface, and the glass layer further including a first surface opposite the second surface, and the microelectronic assembly further comprising:
a through-glass via (TGV) extending between the first surface and the second surface of the glass layer, wherein the TGV includes a conductive material, and wherein the liner material is between the glass layer and the conductive material of the TGV.

16. The microelectronic assembly of claim 15, further comprising:
a first die at least partially embedded in the cavity; and
a second die on the second surface of the glass layer, wherein the second die is electrically coupled to the first die and electrically coupled to the TGV.

17. A microelectronic assembly, comprising:
a glass core having a first surface and an opposing second surface, the glass core including an opening in the second surface and the opening including a sidewall; and
a liner material on the sidewall of the opening in the glass core, wherein the liner material includes a first region having a first width and a second region having a second width less than the first width, and wherein the liner material includes a crosslinked polymer.

18. The microelectronic assembly of claim 17, wherein the crosslinked polymer includes a polyurethane acrylate, an acrylic, a methacrylic polymer, a polyvinyl alcohol, a polyvinyl cinnamate, a polyisoprene, a polyamide, an epoxy, a polyimide, styrenic block copolymers, or a nitrile rubber.

19. The microelectronic assembly of claim 17, wherein the opening in the glass core includes a through-glass via (TGV).

20. The microelectronic assembly of claim 17, wherein the opening in the glass core includes a cavity.
